(19) United States
(12) Patent Application Publication
(10) Pub. No.: US 2026/0311972 A1
(43) Pub. Date: Oct. 8, 2026

(54) INTEGRATION OF VAPOR DEPOSITION PROCESS INTO PLASMA ETCH REACTOR

(71) Applicant: Lam Research Corporation, Fremont, CA (US)

(72) Inventors: Eric A. Hudson, Berkeley, CA (US); Andrew Clark Serino, Oakland, CA (US); Thad Nicholson, San Jose, CA (US); Ramesh Chandrasekharan, Lake Oswego, OR (US); Alan M. Schoepp, Ben Lomond, CA (US)

(21) Appl. No.: 19/711,666

(22) Filed: Jun. 17, 2026

Related U.S. Application Data
(62) Division of application No. 18/003,139, filed on Oct. 22, 2021.
(60) Provisional application No. 63/198,513, filed on Oct. 23, 2020.

(51) Int. Cl. H01J 37/32; C23C 16/02; C23C 16/455; C23C 16/50; C23C 16/56

(52) U.S. Cl. CPC H01J 37/32449; C23C 16/0245; C23C 16/45565; C23C 16/50; C23C 16/56; H01J 37/32458; H01J 37/32816; H01J 37/32357; H01J 2237/2002; H01J 2237/334

(57) ABSTRACT

Various embodiments herein relate to methods and systems for integrating a vapor deposition process and an etch process in a single reactor. The vapor deposition process involves delivery of at least one deposition vapor in the absence of plasma. The etch process is a plasma etch process. Various features may be combined as desired to promote high quality deposition and etching results.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### BACKGROUND

One process frequently employed during fabrication of semiconductor devices is formation of an etched cylinder or other recessed feature in dielectric material. One example context where such a process may occur is memory applications such as DRAM and 3D NAND. As the semiconductor industry advances and device dimensions become smaller, such recessed features become increasingly harder to etch in a uniform manner, especially for high aspect ratio features having narrow widths and/or deep depths.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves an apparatus for processing a substrate, the apparatus including: a processing chamber including : an outer chamber, and a reactor having an inlet and an outlet, the reactor being positioned within the outer chamber; a plasma generator configured to provide plasma in the reactor; and a substrate support; whereby during processing, gas phase species pass from the reactor, through the outlet, into the outer chamber, a flow conductance from the reactor into the outer chamber can be varied and controlled during processing, and when the apparatus is in a low flow conductance state, the flow conductance from the reactor into the outer chamber is about 0.2 sccm/mTorr or less.

In some embodiments, the apparatus further includes a movable pressure control ring proximate the outlet to the reactor, such that the movable pressure control ring is adjustable to vary the flow conductance from the reactor into the outer chamber.

In some embodiments, the apparatus further includes a movable wall within the reactor, such that the movable wall is adjustable to vary the flow conductance from the reactor to the outer chamber.

In some embodiments, the substrate support is configured to be adjustable to vary the flow conductance from the reactor to the outer chamber.

In various embodiments, when the apparatus is in a high flow conductance state, the flow conductance from the reactor into the outer chamber is about 1 sccm/mTorr or greater. In some embodiments, the apparatus also includes a controller configured to cause the apparatus to switch between the low conductance state and the high conductance state while processing the substrate.

Another aspect involves an apparatus for processing a substrate, the apparatus including: a processing chamber including: an outer chamber, and a reactor having an inlet and an outlet, the reactor being positioned within the outer chamber; a plasma generator configured to provide plasma in the reactor and in the outer chamber; substrate support, such that during processing, gas phase species pass from the reactor, through the outlet, into the outer chamber.

In some embodiments, the plasma generator is configured to provide a direct plasma in the reactor, where the direct plasma is not confined to the reactor.

In some embodiments, the plasma generator is configured to generate a remote plasma that is delivered to the outer chamber.

Another aspect involves an apparatus for processing a substrate, the apparatus including: a processing chamber; a substrate support; a bypass pathway having a flow conductance of about 1 sccm/mTorr, or greater; a showerhead including (i) a plurality of orifices that provide gas to the processing chamber, and (ii) a bypass outlet that provides gas to the bypass pathway; and a gas injection pathway configured to provide gas to the showerhead.

Another aspect involves an apparatus for processing a substrate, the apparatus including: a processing chamber; a substrate support; a first inlet to the processing chamber for providing at least a purge gas and a deposition vapor to the processing chamber; an optional second inlet to the processing chamber, such that an etch gas is provided to the processing chamber via the first inlet or via the optional second inlet; a gas injection pathway configured to alternately provide at least the purge gas and the deposition vapor to the first inlet; a purge gas delivery pathway configured to provide the purge gas to the gas injection pathway; a deposition vapor delivery pathway configured to provide the deposition vapor to the gas injection pathway; an etch gas delivery pathway configured to provide the etch gas to the gas injection pathway or to the optional second inlet; a bypass pathway fluidically coupled to the purge gas delivery pathway and to the deposition vapor delivery pathway via valves, such that the bypass pathway does not deliver any gas to the processing chamber; a controller configured to cause (i) alternately flowing the purge gas and the deposition vapor into the processing chamber via the gas injection pathway, and (ii) alternately flowing the purge gas and the deposition vapor through the bypass pathway.

Another aspect involves an apparatus for processing a substrate, the apparatus including: a processing chamber; a plasma generator configured to provide plasma in the processing chamber; substrate support; a first inlet to the processing chamber, the first inlet configured to provide deposition vapor to the processing chamber; a second inlet to the processing chamber, the second inlet configured to provide etch gas to the processing chamber, such that the deposition vapor and etch gas do not mix with one another before passing into the processing chamber; and an outlet to the processing chamber.

In any of the above embodiments, the apparatus may also include a controller configured to cause any of the methods described herein.

These and other aspects are described further below with reference to the drawings.

### BRIEF DESCRIPTION OF THE DRAWINGS

FIG. 1 shows a flow chart for a method of etching a substrate according to various embodiments herein.

FIG. 2 illustrates a combined etching/deposition reactor, depicting various problems that can arise.

FIG. 3 depicts a combined etching/deposition reactor that uses a shared injection pathway for deposition vapors and etch gases.

FIG. 4 shows a combined etching/deposition reactor that has separate injection pathways for deposition vapors and etch gases.

FIG. 5 shows a combined etching/deposition reactor that includes a bypath pathway that enables high flow purging.

FIGS. 6A and 6B illustrate a combined etching/deposition reactor that has a bypath pathway that is used alternately by the deposition vapors and purge gas.

FIG. 7 shows a combined etching/deposition reactor that provides controllable flow conductance using a pressure control ring.

FIG. 8 depicts a combined etching/deposition reactor that provides controllable flow conductance using a movable wall.

FIG. 9 illustrates a combined etching/deposition reactor that provides controllable flow conductance using an adjustable reactor gap.

FIG. 10 shows a combined etching/deposition reactor that has a movable lower reactor assembly that enables formation of an unconfined plasma.

FIG. 11 illustrates a combined etching/deposition reactor that includes a remote plasma source.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Fabrication of various semiconductor devices involves etching features into dielectric material using plasma-based etch processes. In a number of cases, the dielectric material is provided in a stack of materials, which may include alternating layers of materials. For instance, the stack may include any combination of silicon oxide, silicon nitride, and/or polysilicon. Additional layers may be present as desired for a particular application.

One technique for forming high aspect ratio features involves incorporating one or more deposition steps into the etch process. The deposition step(s) may be vapor-based deposition step(s) that involve delivery of a deposition vapor to the reactor. The film deposited by the deposition step(s) may promote passivation or etching at desired locations on the substrate. For instance, the deposited film may passivate the upper sidewalls of the partially etched features, thereby allowing etching at the bottom of the features without lateral etch of the upper sidewalls. The deposition step(s) provide good control over step coverage, thickness, and selectivity to different substrates.

In the embodiments herein, both the etching steps and the deposition step(s) occur in the same processing chamber, such that there is no need to transfer the substrate between separate etch and deposition chambers as the features are being formed. The increased efficiency achieved by avoiding substrate transfer is especially relevant in cases where the deposition step is cycled with the etching step several times during the etch process.

While the use of a combined etching/deposition reactor may provide various benefits such as decreased processing time and increased throughput, there are a number of engineering considerations that arise when combining etching/deposition apparatuses. In order to realize the benefits of the combined etching/deposition reactor in a package that is practical for industrial microelectronics processing, the embodiments herein address a number of potential conflicts between (1) optimal reactor design for plasma etch and (2) optimal reactor design for vapor-based deposition. Generally speaking, plasma etch steps typically occur at low pressure and high conductance (or variable conductance, including high conductance), deposition dosing steps typically occur at high pressure and low conductance, and purge steps typically occur at high pressure and high conductance.

The embodiments herein present a number of different innovations that enable a production-worthy process that combines plasma etch and vapor-based deposition in a single reactor. These innovations generally fall into the following categories: (a) deposition vapor and etch gas injection into the processing chamber, (b) control over variable gas conductance over a wide range of conductance, (c) pumping and purging capability over a wide range of pump flows, and (d) control over buildup of unwanted deposition in the processing chamber. These innovations may be combined as desired for a particular application. Particular embodiments are discussed further below.

As used herein, the term “vapor” is intended to refer to a gas phase species that is provided to the processing chamber without plasma. The term “deposition vapor” is intended to refer to a gas phase reactant provided to the processing chamber without plasma during a deposition operation. Similarly, the term “vapor-based deposition” is intended to refer to deposition that involves delivery of a deposition vapor to the processing chamber without concurrent plasma. Example vapor-based deposition schemes include, e.g., molecular layer deposition, self-assembled monolayer deposition, thermally driven atomic layer deposition, and plasma-driven atomic layer deposition that involves delivery of a deposition vapor without exposure to plasma (e.g., in such cases, plasma is used to drive a reaction after delivery of the deposition vapor has ceased). The vapor species used herein are typically based on chemicals that have relatively low vapor pressures, which make them impractical to use with conventional plasma-etch gas delivery systems including thermal mass flow controllers. Such chemicals are typically in liquid or solid form under ambient conditions. As such, unwanted condensation of vapors is a common issue. By contrast, the term “gas” is used more generally, and may refer to species that are provided to the processing chamber with or without plasma. The term “etch gas” is intended to refer to a reactant provided to the processing chamber during an etching operation. In many cases, the etch gas is provided to the chamber while plasma is present in the chamber. Commonly used etch gases typically have sufficiently high vapor pressure to allow the use of conventional thermal mass flow controllers.

As used herein, the term “low pressure” is intended to mean a pressure of about 800 mTorr or less, unless stated otherwise. The term “high pressure” is intended to mean a pressure of about 1 Torr or greater, unless stated otherwise. The term “low conductance” is intended to mean a conductance of about 0.05 sccm/mTorr or less, unless stated otherwise. The term “high conductance” is intended to mean a conductance of about 1 sccm/mTorr or greater, unless stated otherwise.

### I. Process Flow

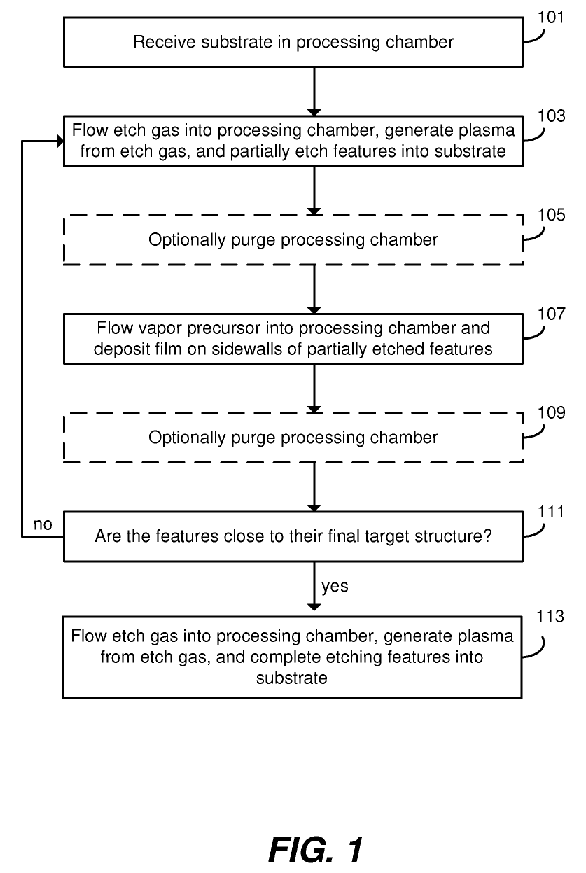

FIG. 1 illustrates a flow chart for a method of etching a recessed feature in line with various embodiments herein. The method of FIG. 1 begins at operation 101, where a substrate is received in a processing chamber. The substrate has a stack of materials thereon, which includes dielectric material. The dielectric material may be silicon oxide and/or silicon nitride. Additional layers of material may be provided as desired for a particular application. Example material stacks are discussed further below. A patterned mask layer is provided above the dielectric material. The pattern in the mask layer defines where the features are to be formed in the stack.

Next, at operation 103, etch gas is flowed into the processing chamber and a plasma is generated from the etch gas. The substrate is exposed to the plasma and the features are partially etched in the stack. Then, at operation 105, the processing chamber is optionally purged to remove excess etch gas and/or etch byproducts. The purge step helps reduce unwanted reactions between the etch gas and a deposition vapor that will be introduced later on during processing. The purge may involve delivery of a purge gas and/or evacuation of the processing chamber. In various cases, the purge operation 105 may also result in purging some or all of the delivery lines used to provide the etch gas to the processing chamber, including, e.g., any delivery lines that are shared between the etch gas and a deposition vapor.

At operation 107, a deposition vapor is flowed into the processing chamber and a film is deposited on the sidewalls of the partially etched features. Depending on the deposition mechanism, an additional reactant may or may not be provided. For example, where the film is deposited as a self-assembled monolayer, no additional reactant is required. On the other hand, where the film is deposited through molecular layer deposition or atomic layer deposition, for instance, the deposition vapor and the additional reactant may be provided to the processing chamber in a cyclic manner. In some cases, the deposition is conformal. The film may or may not extend along the entire length of the sidewalls. In some cases, the film is concentrated near the upper portions of the sidewalls, but is much thinner or non-existent near the bottom portions of the sidewalls.

At operation 109, the process continues with another optional purge of the processing chamber to remove excess deposition reactants (e.g., the deposition vapor and any additional reactants) and byproducts. In various cases, the purge operation 109 may also result in purging some or all of the delivery lines used to provide the deposition vapor to the processing chamber, including, e.g., any delivery lines that are shared between the etch gas and a deposition vapor.

At operation 111, it is determined whether the features are close to their final target structure. If yes, the method continues at operation 113, where etch gas is flowed into the processing chamber, plasma is generated from the etch gas, the features are etched a final time. At this point, the method is complete. If it is determined at operation 111 that the features are not close to their final target structure, the method repeats from operation 103, where another partial etching step is performed. The operations in FIG. 1 are cycled until the features reach their final target structure.

### II. Potential Risks and Focus Areas

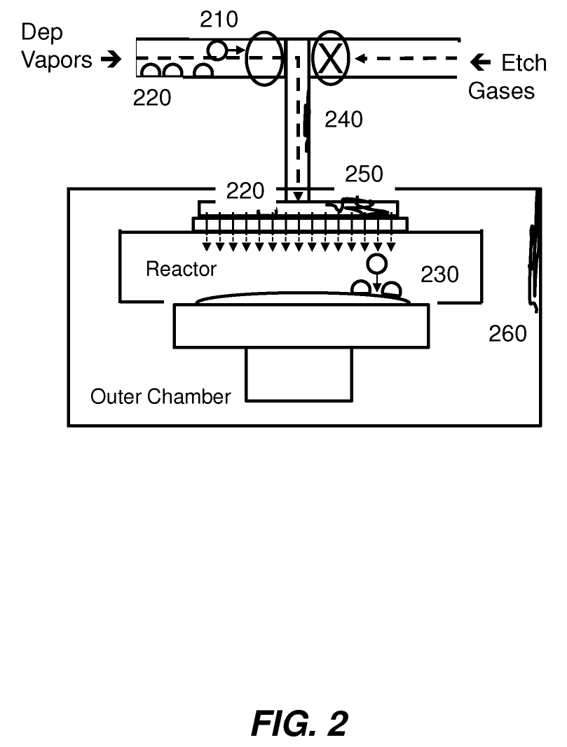

FIG. 2 illustrates an apparatus that is used for both etching and deposition, showing some of the problems that can arise when these processes are combined on a single apparatus. The apparatus shown has a design which confines the etching plasma to an inner region of the vacuum chamber. This inner region is referred to as the “reactor.” During processing, a substrate is positioned on a substrate support, and is exposed to the conditions in the reactor. For example, during etching the substrate is exposed to etching plasma that is confined within the reactor. The outer part of the vacuum chamber is not exposed to plasma and is referred to as the “outer chamber.” This design is commonly used for capacitively coupled dielectric etch systems such as the Lam Research Corp, Flex^{®} family of products. For the purposes of the discussion below, this configuration is assumed. However, the techniques disclosed herein are not limited to this particular apparatus configuration. Such techniques may be applied to other apparatus configurations for plasma etching.

In the example of FIG. 2, the deposition vapors and etch gases are selectively delivered to the processing chamber through a shared delivery line. One issue that can arise is unwanted condensation of the deposition vapors. Condensed deposition vapor 210 may form liquid residue 220, for example in the delivery lines and/or in a plenum on the back side of the showerhead. This condensation can occur because the variation of vapor temperature and pressure in time and space may create a condition where the liquid state is more favorable than the vapor state. This liquid residue 220 may prevent efficient purging of the vapor delivery path. In some cases, the liquid residue 220 may form droplets that are aerosolized, which can lead to the formation of unwanted particles 230 that deposit on the surface of the substrate.

Another issue that can arise during processing is the formation of unwanted material on surfaces of the processing apparatus (e.g., reactor surfaces, processing chamber surfaces, delivery lines, showerheads, etc.). In many cases, this unwanted material forms from a reaction between the etch gases and the deposition vapors. For example, unwanted deposition 240 may form in the shared delivery line that provides both the etch gases and deposition vapors to the processing chamber. Likewise, unwanted deposition 250 may form in the plenum on the back side of the showerhead, and/or in showerhead holes (not shown). The unwanted depositions 240 and 250 are especially likely to form in areas where both liquid residue 220 and etch gases are present, for example in hardware shared by the deposition vapors/etch gases. While the deposition vapors and etch gases are not actively introduced at the same time, residual amounts of vapors or gases may remain in the delivery path, in gaseous form and/or adsorbed or condensed on a surface, with the potential for unwanted cross-reactions to occur. In a particular example, unwanted depositions 240 and 250 may form from a reaction between HBr (e.g., flowing to the reactor as an etch gas) and the residue of a diamine deposition vapor used in a preceding molecular layer deposition step.

Unwanted deposition 260 can also form on the walls of the outer chamber. The unwanted deposition 260 may be a residue from an unwanted side reaction, for example (1) a reaction between the deposition vapor and etch gas, (2) a reaction between the deposition vapor and byproducts of the etching process/etch gas plasma, (3) a reaction between the deposition vapor and byproducts of the deposition reaction. In some cases, unwanted deposition 260 may be a polymer, for example, a polymer that forms as a result of a molecular layer deposition reaction.

Conventional etching reactors based on a confined plasma configuration and used only for etching operations typically produce little or no deposition on the walls of the outer chamber. As such, there hasn’t been any need or reason to include a mechanism for removing such deposition from the walls of the outer chamber in conventional etching apparatus. Instead, such reactors are often equipped with plasma generators that can be used to autoclean the reactor surfaces. These autoclean processes do not reach the outer chamber, and therefore do not act to remove unwanted deposition in this region.

Another issue that should be addressed when performing both etching and deposition in the same reactor is optimization of the flow conductance through the reactor for each process. For example, etching typically occurs over an adjustable medium to high conductance range (e.g., between about 1-50 sccm/mTorr). In many cases, plasma etching occurs at relatively high conductance, and plasma autocleaning of the reactor occurs at a medium conductance. By contrast, deposition typically occurs at relatively low conductance (e.g., between about 0.001-0.03 sccm/mTorr) to enable both high pressure and high dose in the reactor, and a low pressure and low dose in the outer chamber. The low conductance during deposition enables shorter dose times in the reactor, with better utilization of the deposition vapor. The low dose in the outer chamber also minimizes unwanted deposition in the outer chamber.

As such, when both etching and deposition occur in the same reactor, it is beneficial to ensure that the conductance through the reactor is variable and controllable over a wide range. This variable conductance is illustrated by the sets of downward-pointing arrows leading from the reactor to the outer chamber. Where variable conductance is used, it is also beneficial to ensure that the conductance can be changed rapidly in order to maximize throughput.

### III. Etching

Generally speaking, the embodiments herein are not limited to particular etchant species or etching conditions, and the etching step may be carried out using conventional processing conditions. Example processing conditions are discussed in the following US Patents, each of which is incorporated herein by reference in its entirety: US Patent No. 9,384,998, US Patent No. 9,887,097, US Patent No. 9,997,373.

In some embodiments, the pressure during etching may be between about 10-200 mTorr (e.g., in the case of a capacitively coupled plasma), or between about 1-120 mTorr (e.g., in the case of an inductively coupled plasma). Example flow rates for the etch gas may be between about 100-3000 sccm. Turbomechanical pumping may be used during the etch to remove excess etch gases and etch byproducts from the processing chamber, with maximum turbomechanical pump flows typically around 3000 sccm.

In many cases, etching involves generating a plasma from an etch gas and exposing the substrate to the plasma. The etch gas may include, e.g., a chlorine source, a bromine source, a carbon source, a fluorine source, an oxygen source, and/or a hydrogen source. In various embodiments, a combination of different etch gases may be used. Example gases that may be provided in the etch gas include, but are not limited to, chlorine gas (Cl₂), hydrogen chloride (HCl), carbonyl sulfide (COS), fluorocarbons (CxFy), hydrofluorocarbons (CₓH_{y}F_{z}), chlorocarbons (CₓCl_{y}), hydrochlorocarbons (CₓH_{y}Cl_{z}), nitrogen trifluoride (NF₃), hydrogen bromide (HBr), trifluoroiodomethane (CF₃I), oxygen (O₂), hydrogen (H₂), etc. The etch gas may also include one or more inert gases.

Certain features may be provided in the etching/deposition reactor to promote high quality etch results. These features may include any combination of the following: (1) multizone gas injection to promote control of process uniformity, (2) showerhead gas injection for uniform gas delivery, (3) corrosion-resistant gas line materials such as nickel-chromium-molybdenum alloy, and/or (4) controlled variable gas conductance (e.g., including both low conductance and high conductance). Further details are provided in the Examples below.

### IV. Deposition

A number of different vapor-based deposition mechanisms may be used according to various embodiments. In some cases, molecular layer deposition is used. In some cases, self-assembled monolayer deposition is used. In some cases, atomic layer deposition is used. Where atomic layer deposition is used, the reaction may be thermally driven or plasma driven. Where the atomic layer deposition reaction is plasma driven, there is at least one step that involves delivering a deposition vapor to the processing chamber without a concurrent plasma. Other vapor-based deposition mechanisms may be used as appropriate for a particular application.

The embodiments herein are not limited by any particular deposition vapors or deposition conditions. The deposition steps may take place using conventional deposition conditions. In many cases, the deposition steps are designed to deposit a thin film with known and controlled composition on the substrate, for example on the sidewalls of partially etched features. Vapor-based deposition processes typically take place at pressures between about 1-40 Torr. The relatively high deposition pressure enables relatively short processing times due to higher flux of species reaching the substrate surface. Conventional deposition reactors typically have the capability to provide flows of >5 SLM at high pressures (e.g., >2 Torr) to enable rapid and effective purging. Purging is particularly beneficial in cases where alternating chemistries are cycled with one another, for example to prevent unwanted reactions between a residual vapor and a subsequent reactant.

A number of features may be provided in the etching/deposition reactor to promote high quality deposition results. These features may include any combination of the following: (1) efficient high pressure/high flow purging, with minimal dead legs in the vapor path, (2) point of use valves that enable rapid purge with no dead legs, (3) heated point of use valves designed to minimize risk of vapor condensation in steady state and while opening or closing, (4) controlled and progressively higher wall temperature along the deposition vapor delivery path from the deposition vapor source to the processing chamber, (5) designs to avoid condensation by preventing rapid expansion of vapor, for example avoiding flow through small orifices, and (6) heated chamber walls to reduce unwanted deposition on these surfaces. Where heated components are used, temperatures may be chosen to reduce adsorption of deposition vapors or other reactants, while avoiding unwanted decomposition that may occur at higher temperatures, for example above about 250° C in some cases where organic reactants are used. These features may be combined with those listed above as promoting high quality etching results. Further details are provided in the Examples below.

### V. Examples

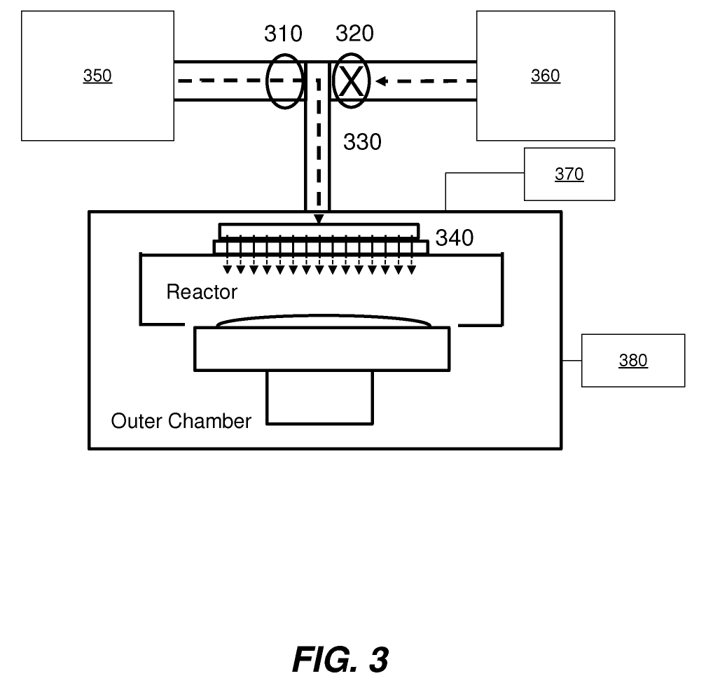

FIGS. 3-11 depict a number of implementations in line with the embodiments herein. Various features are discussed in relation to these examples. While the features may be described in connection with a particular example, it is understood that the features may be combined as desired for a particular application.

### A. Shared Injection for Deposition Vapor and Etch Gas

FIG. 3 illustrates a combined etching/deposition reactor according to various embodiments. In this example, there is an injection path 330 that is used to alternately deliver the deposition vapors and the etch gases. The deposition vapors originate from a vapor source 350, and the etch gases originate from etch gas source 360. For ease of illustration, the vapor source 350 and etch gas source 360 are omitted from the remaining figures, though it is understood that they are included. Similarly, FIG. 3 illustrates plasma generator 370, which is omitted from the remaining figures, but is understood to be included. Plasma generator 370 may be configured to provide a capacitively coupled plasma in the reactor. Other types of plasma may be provided in certain cases. Valve 310 controls delivery of the deposition vapors, and valve 320 controls delivery of the etch gases. Valves 310 and 320 may be point of use valves. Example valve structures are discussed in US Patent Publication No. 2013/0333768, filed Sep. 25, 2012, and in US Patent Publication No. 2019/0323125, filed Apr. 18, 2018, each of which is incorporated by reference in its entirety. The valve structures described in these publications enable rapid purging with no dead legs in the delivery system. Generally speaking, any of the valves described herein may be point of use valves.

In the example of FIG. 3, both the deposition vapor and the etch gas are selectively injected into the reactor of the processing chamber through a single shared showerhead 340. Various alternatives are available. For instance, the deposition vapor may be separately provided through another delivery system such as a gas ring, one or more nozzles, a dual showerhead with separate delivery paths for deposition vapor and etch gas, etc.

Also shown in FIG. 3 is controller 380, which may be used to control the apparatus to cause the methods and operations described herein. The controller 380 is omitted from the remaining figures, though it is understood that such a controller is typically present. The controller is discussed further below.

One advantage of the embodiment in FIG. 3 is its simplicity. Because only a single showerhead is used, the hardware cost is relatively low. Another advantage of the embodiment in FIG. 3 is that it provides highly uniform flux of both the deposition vapor and the etch gas to the substrate, since both species are delivered through the showerhead. This promotes a high degree of process uniformity. In the embodiment shown in FIG. 3, there may be a risk of unwanted side reactions between the flowing deposition vapor and etch gas residues, or between the flowing etch gas and deposition vapor residues. In order to minimize these unwanted side reactions, relatively more substantial purging conditions may be used, for example very long purge times of longer than 5 seconds.

### B. Separate Injection for Deposition Vapor and Etch Gas

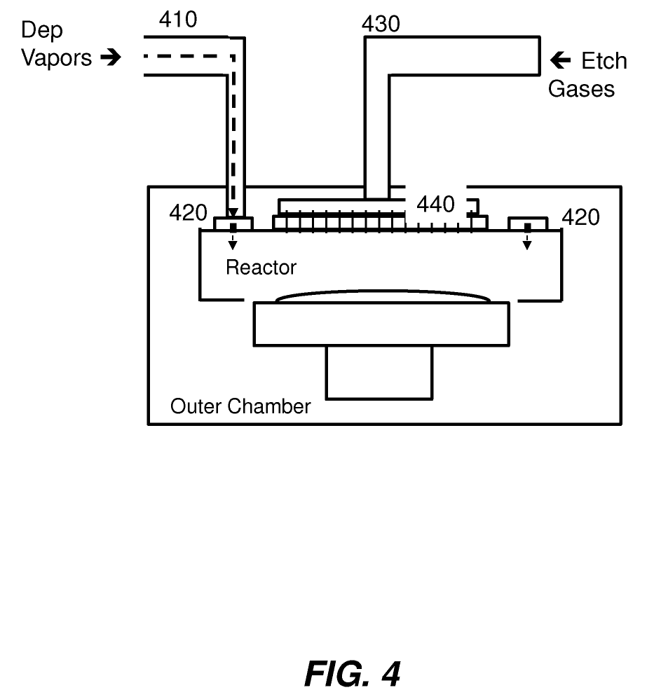

FIG. 4 illustrates a combined etching/deposition reactor according to various embodiments. In this example, separate delivery lines are provided to deliver the deposition vapors and the etch gases to the reactor. The deposition vapor delivery path 410 delivers the deposition vapor to a plenum and gas ring 420, while the etch gas delivery path 430 delivers the etch gas to a plenum and showerhead 440.

One advantage of the embodiment in FIG. 4 is that the deposition vapor and the etch gas have no contact with one another before delivery to the reactor, thereby minimizing the risk of unwanted side reactions between flowing deposition vapors and etch gas residues, and between flowing etch gases and deposition vapor residues. The embodiment in FIG. 4 may provide less uniform flux of deposition vapor on the substrate, as compared to the embodiment of FIG. 3 where the deposition vapor is delivered through a showerhead. However, because the deposition mechanism typically relies on monolayer adsorption or may otherwise be self-limiting, even the less uniform flux provided in FIG. 4 may be sufficient to provide high quality deposition results.

In another embodiment similar to FIG. 4, a dual showerhead may be provided. The dual showerhead provides separate, isolated pathways for delivery of the deposition vapor and the etch gas. The deposition vapor delivery path 410 and etch gas delivery path 430 can each feed into separate ports of the dual showerhead, ensuring that the deposition vapor and etch gas remain physically separated until reaching the reactor. In another embodiment similar to FIG. 4, the deposition vapor may be injected into the reactor from the side of the reactor (rather than from the top, as shown in FIG. 4).

### C. Bypass Purge Path

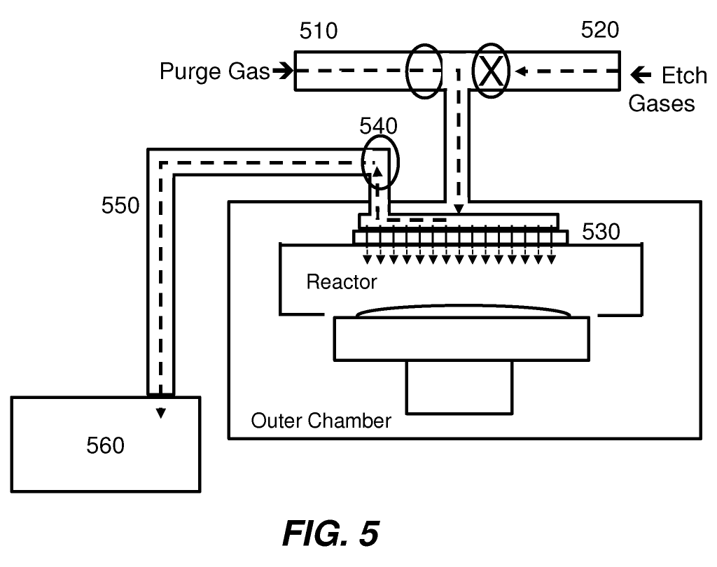

FIG. 5 illustrates a combined etching/deposition reactor according to various embodiments. In the embodiment of FIG. 5, the deposition vapor and the etch gas are delivered to the reactor through showerhead 530. The vapor delivery path 510 and the etch gas delivery path 520 feed into a single injection path that feeds the showerhead 530. The purge gas is likewise provided to the reactor through the showerhead 530, after passing through the deposition vapor delivery path 510 and the injection path shared by the deposition vapor and the etch gas. In this example, the showerhead 530 includes two types of outlets including (1) a plurality of small orifices for delivering etch gas, deposition vapor, and purge gas to the reactor, and (2) a bypass outlet 540 for removing gas (e.g., purge gas) from the showerhead 530 at a relatively high rate. The bypass outlet feeds a bypass pathway 550 connected to a high capacity pump 560. The bypass pathway 550 is a high conductance path (e.g., >1 sccm/mTorr). The high capacity pump 560 may support a flow of >3000 sccm, for example. Valve 540 controls flow through the bypass pathway 550.

In cases where the bypass pathway 550 is absent, the showerhead 530 limits the maximum achievable flow of purge gas into the reactor. This limitation arises due to the configuration of the showerhead 530 with its array of small orifices that result in relatively low conductance. By contrast, where bypass pathway 550 and high capacity pump 560 are present, the purge gas may flow at a much higher rate, limited only by the conductance of bypass pathway 550 and the pumping capacity of high capacity pump 560.

Because the purge gas is able to flow at a higher rate, unwanted residues (e.g., from deposition vapors or etch gases) can be removed more efficiently. This enables shorter purge times, which increases throughput. Purge times that may be shortened include purges between process steps based on deposition vapors and etch gasses, as well as purges between process steps based on different deposition vapors and/or additional reactants during deposition (e.g., where cyclic deposition methods such as molecular layer deposition or atomic layer deposition are used). The embodiment in FIG. 5 including the valve 540, bypass pathway 550, and high capacity pump 560 may add cost, power consumption, and complexity to the system.

### D. Bypass for Minimizing Pressure Drop

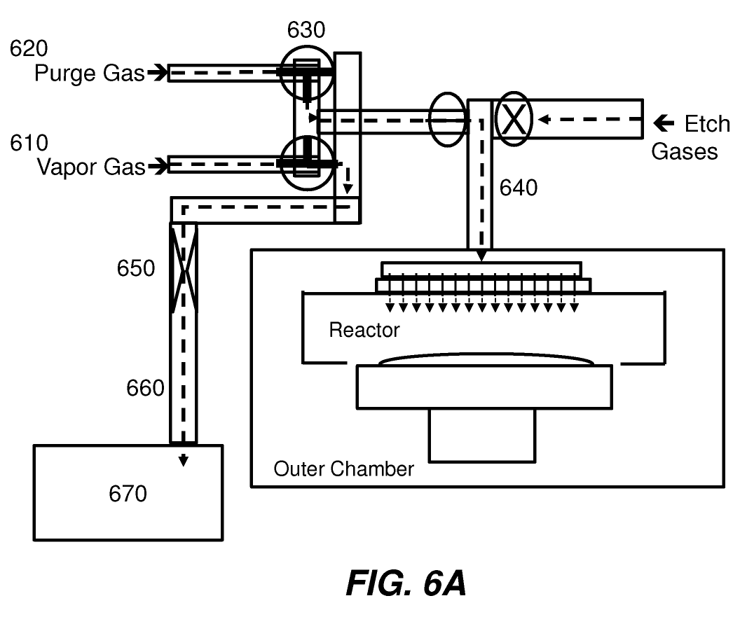

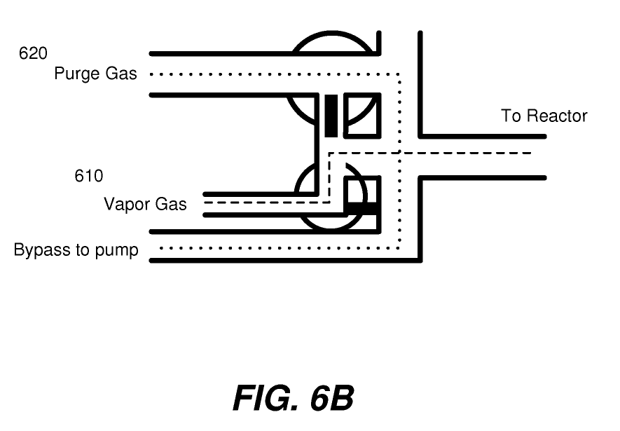

FIGS. 6A and 6B illustrate a combined etching/deposition reactor according to various embodiments. In this example there is a bypass pathway 660 that is alternately shared between the deposition vapor (delivered via deposition vapor delivery path 610) and the purge gas (delivered via purge gas delivery path 620). For example, FIG. 6A shows a valve configuration 630 that allows the deposition vapor to flow through the bypass pathway 660 while the purge gas is delivered to the processing chamber. By contrast, FIG. 6B shows a valve configuration 680 that allows the purge gas to flow through the bypass pathway 660 while the deposition vapor is delivered to the processing chamber.

A pump 670 drives flow along the bypass pathway 660. The pump 670 may be a high capacity pump as described in relation to FIG. 5, or it may be a turbomechanical pump. Similarly, the bypass pathway 660 may be a high conductance path as described in relation to FIG. 5, or it may have a lower conductance. A flow restrictor 650 may be provided in the bypass pathway 660. The flow restrictor 650 may be a fixed-size orifice or an adjustable needle valve, for example. The flow restrictor 650 may be configured to vary/control the flow conductance within the bypass pathway 660 such that it matches the flow conductance of the injection path 640 that alternately delivers the deposition vapor/purge gas to the reactor within the processing chamber. The bypass pathway 660 allows for the flow of the deposition vapor and purge gas to be established/stabilized before they are directed to the reactor of the processing chamber. This configuration minimizes the local pressure fluctuations nearby the valves 630 or 680, when switching between purge gas and deposition vapor. This avoids unwanted condensation of deposition vapor during switching.

One advantage of the embodiment in FIGS. 6A and 6B is that the shared bypass pathway 660, with controlled conductance and associated valving, minimize the local pressure fluctuations nearby the valves 630 or 680 when switching between the purge gas and the deposition vapor. This reduces the risk of unwanted condensation of deposition vapor during switching. Because there is less risk of condensation, it is less likely that unwanted side reactions will occur, and that unwanted particles will form on the substrate or reactor surfaces, as explained in relation to FIG. 2. The embodiment in FIGS. 6A and 6B including the bypass pathway 660, flow restrictor 650, and pump 670 may add cost and complexity to the system.

### E. Pressure Control Ring for Variable Conductance

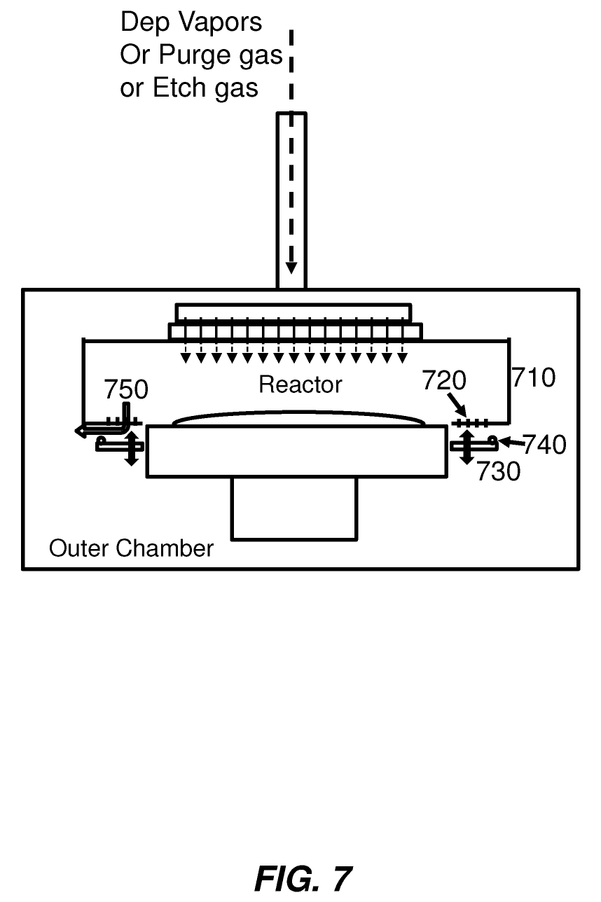

FIG. 7 illustrates a combined etching/deposition reactor according to various embodiments. This example depicts one mechanism for providing variable flow conductance 750 from the reactor to the outer chamber. The reactor is defined, at least in part, by a confinement shroud 710. Gas phase species pass from the reactor, through outlet 720, to the outer chamber. Outlet 720 may be formed as a slotted or otherwise perforated portion of the confinement shroud 710, as shown.

In FIG. 7, a pressure control ring 730 is positioned proximate the outlet 720. The height of the pressure control ring 730 is adjustable in order to provide a wide range of flow conductance from the reactor to the outer chamber. For example, when the pressure control ring 730 is in an upper position (relatively closer to the outlet 720), the flow from the reactor into the outer chamber is more restricted, resulting in a lower flow conductance. By contrast, when the pressure control ring 730 is in a lower position (relatively farther from the outlet 720), the flow from the reactor into the outer chamber is less restricted, resulting in a higher flow conductance.

For this embodiment of the combined etching/deposition reactor, in order to further reduce the flow conductance when the pressure control ring 730 is positioned at the upper position, an elastomeric seal 740 may be provided, for example above an upper surface of the pressure control ring 730 (as shown in FIG. 7), or below a lower surface of the reactor. The elastomeric seal 740 may engage to prevent or substantially limit flow from the reactor to the outer chamber, creating a very low conductance state. This very low conductance state is particularly useful during vapor deposition, for example during dose steps where the deposition vapor(s) are provided to the reactor and allowed to adsorb onto the substrate surface.

In various embodiments where a pressure control ring is used, the conductance from the reactor to the outer chamber is tunable over a wide range. For instance, in some cases the conductance may tuned as low as about 0.01 sccm/mTorr when the pressure control ring 730 is in the uppermost position, and may be tuned as high as about 50 sccm/mTorr when the pressure control ring 730 is in the lowermost position. During processing, the pressure control ring 730 may be positioned at a relatively higher position (e.g., the uppermost position) during certain deposition steps, for example when a vapor precursor is being dosed to the reactor. By contrast, the pressure control ring 730 may be positioned at a relatively lower position (e.g., the lowermost position) during other processing steps such as etch steps and/or purge steps.

One advantage of the embodiment in FIG. 7 is that the pressure control ring 730 enables a wide control range for the flow conductance from the reactor to the outer chamber. This allows for the etching and deposition steps to take place at substantially different processing conditions. Further, it allows very different conditions to be simultaneously established within the reactor vs. in the outer chamber. For instance, during the vapor deposition process, the pressure in the reactor can be much higher than the pressure in the outer chamber. In a particular example, the pressure in the reactor may be a high pressure, as defined above, and the pressure in the outer chamber may be < 20 mTorr. This configuration allows for efficient dosing of the substrate with deposition vapors, with much lower dosing in the outer chamber, reducing the risk of unwanted deposition in the outer chamber. Another advantage of the embodiment in FIG. 7 is that the pressure control ring 730 can be moved rapidly, allowing for fast transitions from dose steps (where low conductance is desired) to purge steps (where high conductance is desired), and vice versa. In the embodiment shown in FIG. 7, the entire reactor may be exposed to the chemistry of the vapor deposition process.

### F. Movable Wall for Variable Conductance

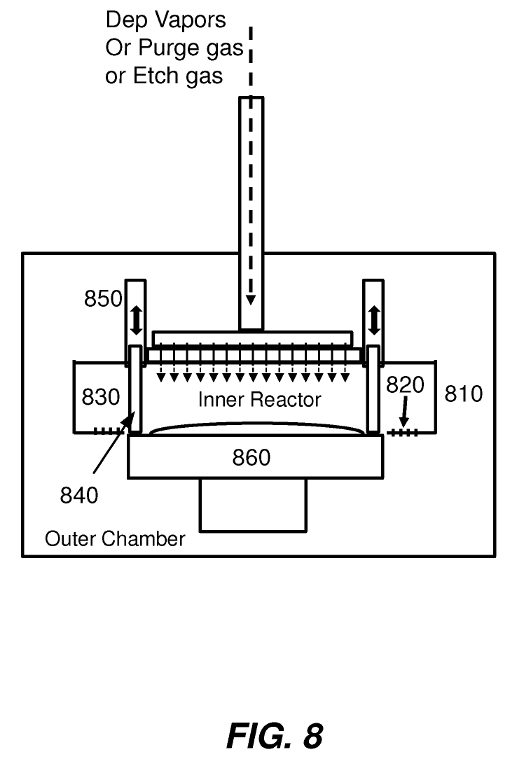

FIG. 8 illustrates a combined etching/deposition reactor according to various embodiments. This example depicts another mechanism for providing variable flow conductance from the reactor to the outer chamber. The reactor is defined, at least in part, by confinement shroud 810. A movable wall or partition 840 splits the reactor into an inner reactor region (labeled “inner reactor” in FIG. 8) and a peripheral reactor region (labeled “830” in FIG. 8). The inner reactor region is radially interior of the movable wall 840, while the peripheral reactor region 830 is between the inner reactor region and the outer chamber. During processing, gas phase species pass from the inner reactor region, under movable wall 840, into peripheral reactor region 830, through outlet 820, and into the outer chamber. In this implementation, the outlet 820 is provided as a slotted or otherwise perforated portion of the confinement shroud 810.

Notably, the movable wall 840 can be raised and lowered as desired. The movable wall 840 extends in a ring shape around the periphery of the showerhead and substrate. In this example, the lower portion of the movable wall 840 engages with an upper surface of the substrate support 860 when the movable wall 840 is in its lowermost position. In an alternative embodiment, the lower portion of the movable wall 840 may engage with a portion of the confinement shroud 810, for example at a position radially inside of the outlet 820. When the movable wall 840 is relatively lower, the flow from the inner reactor region to the peripheral reactor region is more restricted, and the associated flow conductance is lower. When the movable wall 840 is raised, some or all of the movable wall 840 recedes into pocket 850, thereby removing/lessening the restriction on flow, and providing relatively greater conductance.

In some embodiments, an elastomeric seal (not shown) may be provided between the lower portion of the movable wall 840 and the surface with which the movable wall 840 engages when in its lowest position. For instance, such a seal may be provided below a bottom surface of the movable wall 840, above an upper surface of the substrate support, or above an upper surface of the confinement shroud 810. Similarly, in some embodiments, an elastomeric seal (not shown) may be provided between the upper portion of the movable wall 840 and a surface on the confinement shroud 810 or pocket 850 with which the movable wall 840 engages when in its lowest position.

In various embodiments where a movable wall 840 is used, the conductance from the reactor to the outer chamber is tunable over a wide range. For instance, in some cases the conductance may be tuned as low as about 0.01 sccm/mTorr when the movable wall 840 is in its lowermost position, and may be tuned as high as about 50 sccm/mTorr when the movable wall 840 is in its uppermost position. During processing, the movable wall 840 may be positioned at a relatively lower position (e.g., the lowermost position) during certain deposition steps, for example when a vapor precursor is being dosed to the inner reactor region. By contrast, the movable wall 840 may be positioned at a relatively higher position (e.g., the uppermost position) during other processing steps such as etch steps and/or purge steps.

One advantage of the embodiment in FIG. 8 is that it provides a wide control range for flow conductance, much like the embodiment of FIG. 7. The embodiment of FIG. 8 also allows for the vapor deposition process and the etch process to occur at substantially different processing conditions. Moreover, the embodiment of FIG. 8 enables very different processing conditions to be established simultaneously in the inner reactor region vs. the peripheral reactor region 830 vs. the outer chamber. Another advantage of this embodiment is that the inner reactor region is exposed to the vapor deposition process/chemistry, with much lower dosing in the peripheral reactor region and outer chamber, reducing the risk of unwanted deposition in those regions. This in turn reduces the total amount of deposition vapor required for dosing the substrate. Further, because the movable wall 840 effectively reduces the relevant processing volume surrounding the substrate when the movable wall 840 is in its lowermost position, the duration of fill times and purge steps can be reduced. The fill time is the time it takes to reach a target pressure during a dosing step. As such, for a given target dose, the shorter fill time correlates with a shorter dose duration. In the embodiment shown in FIG. 8, it may take a relatively longer time (e.g., up to several seconds) to vary the position of the movable wall 840 as desired between steps.

### G. Adjustable Reactor Gap for Variable Conductance

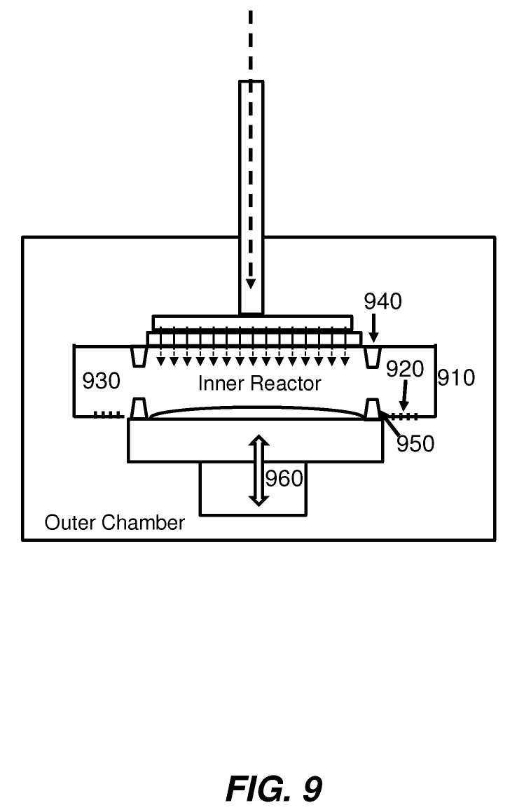

FIG. 9 illustrates a combined etching/deposition reactor according to various embodiments. This example depicts another mechanism for providing variable flow conductance from the inner reactor region to the outer chamber. As noted above, the reactor is defined, at least in part, by confinement shroud 910. Upper reactor lip 940 and lower reactor lip 950 split the reactor into an inner reactor region (labeled “inner reactor” in FIG. 9) and a peripheral reactor region (labeled “930” in FIG. 9). The inner reactor region is radially interior of the upper and lower reactor lips 940 and 950, while the peripheral reactor region is between the inner reactor region and the outer chamber. During processing, gas phase species pass from the inner reactor region, between upper reactor lip 940 and lower reactor lip 950, into the peripheral reactor region 930, through outlet 920, into the outer chamber. In this implementation, the outlet 920 is provided as a slotted or otherwise perforated portion of the confinement shroud 910.

In this example, the lower reactor assembly 960 has an adjustable height. This means that the height of the gap between the lower reactor assembly 960 and the showerhead is adjustable. The lower reactor assembly 960 includes at least the substrate support and the lower reactor lip 950. When the lower reactor assembly 960 is in a relatively lower position, there is less restriction on the flow from the inner reactor region to the peripheral reactor region and into the outer chamber, thereby providing relatively greater flow conductance. By contrast, when the lower reactor assembly 960 is in a relatively higher position, the upper and lower reactor lips 940 and 950 approach one another, thereby restricting the flow from the inner reactor region to the peripheral reactor region and into the outer chamber and providing relatively lower flow conductance.

In various cases, the upper and lower reactor lips 940 and 950 may come into contact with one another, thereby sealing the inner reactor region. In some embodiments, an elastomeric seal (not shown) may be provided between the upper reactor lip 940 and the lower reactor lip 950, for the same reasons as discussed in relation to FIG. 7. The elastomeric seal may be provided on either or both of the upper and lower reactor lips 940 and 950.

In various embodiments where a movable lower reactor assembly 960 is used in combination with upper and lower reactor lips 940 and 950 as shown in FIG. 9, the conductance from the inner reactor region to the outer chamber is tunable over a wide range. For instance, in some cases the conductance may be tuned as low as about 0.01 sccm/mTorr when the movable lower reactor assembly 960 is in its uppermost position, and may be tuned as high as about 50 sccm/mTorr when the movable lower reactor assembly 960 is in its lowermost position. During processing, the movable lower reactor assembly 960 may be positioned at a relatively higher position (e.g., the uppermost position) during certain deposition steps, for example when a vapor precursor is being dosed to the inner reactor region. By contrast, the movable lower reactor assembly 960 may be positioned at a relatively lower position (e.g., the lowermost position) during other processing steps such as etch steps and/or purge steps.

One advantage of the embodiment in FIG. 9 is that it provides a wide control range for flow conductance, much like the embodiments in FIGS. 7 and 8. Similar to those implementations, the embodiment in FIG. 9 enables the etching and deposition operations to take place at different processing conditions. Likewise, this embodiment allows for very different processing conditions to be simultaneously established in the inner reactor region vs. the peripheral reactor region vs. the outer chamber. For example, the vapor deposition process can operate at a much higher pressure within the inner reactor region, as compared to the lower pressure simultaneously established in the peripheral reactor region and in the outer chamber. This minimizes dosing in the peripheral reactor region and in the outer chamber, reducing the risk of unwanted deposition in these areas. Another advantage of this embodiment is that the smaller volume of the inner reactor region (as compared to the entire reactor) can be filled and purged more quickly. This embodiment may take a relatively longer time (e.g., up to several seconds) to position the lower reactor assembly 960 each time it is moved.

### H. Outer Chamber Clean by Unconfined Plasma

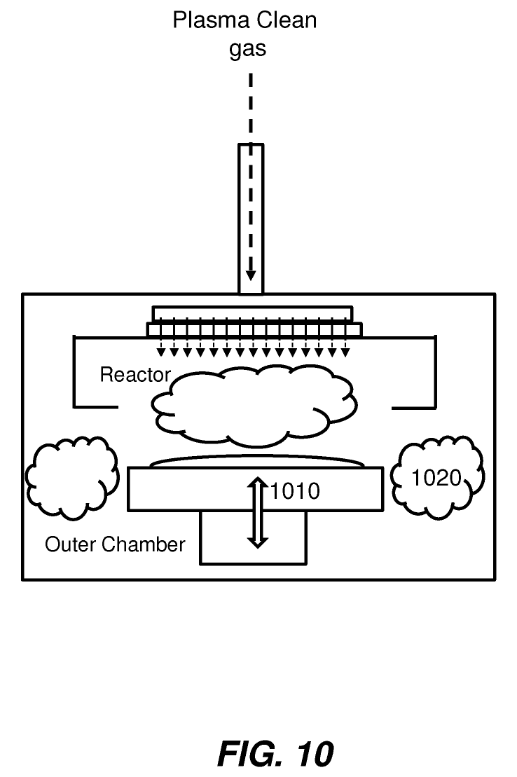

FIG. 10 illustrates a combined etching/deposition reactor according to various embodiments. In this example, the lower reactor assembly 1010 has an adjustable height. The lower reactor assembly 1010 includes at least the substrate support. FIG. 10 shows the lower reactor assembly 1010 at a relatively lower position (e.g., the lowermost position). By contrast, when the reactor assembly 1010 is at a relatively higher position (e.g., the uppermost position), it may resemble the apparatus shown in FIG. 3 (e.g., considering the relative heights of the reactor and the lower reactor assembly).

When the lower reactor assembly 1010 is at its relatively higher position, any plasma generated in the reactor is confined to the reactor. Such a confined plasma is useful for processing substrates, for example during an etching operation. This positioning is also useful for the vapor deposition steps. By contrast, when the lower reactor assembly 1010 is in its relatively lower position, plasma generated in the reactor (e.g., from a plasma clean gas such as O₂) is no longer confined to this volume. Instead, the plasma is sustained in both the reactor and in the outer chamber. For example, plasma 1020 may be present in the outer chamber. Therefore, the plasma may be able to reach and clean unwanted residues from the surfaces (e.g., walls) of the outer chamber. Because conventional etching reactors have substantially not produced unwanted buildup on the surfaces of the outer chamber, there has not been any need or reason to provide a mechanism to clean these surfaces. By contrast, such unwanted buildup may be problematic in cases where both etching and deposition occur on the same substrate in the same reactor. In these cases, it is beneficial to periodically or intermittently clean the surfaces of the outer chamber.

One advantage of the embodiment of FIG. 10 is that it controls buildup of residues in the outer chamber. In this embodiment, because the components of the outer chamber (e.g., the walls and any other exposed components) are exposed to plasma, such components should preferably be fabricated from materials that are compatible with plasma exposure.

### I. Outer Chamber Clean by Remote Plasma

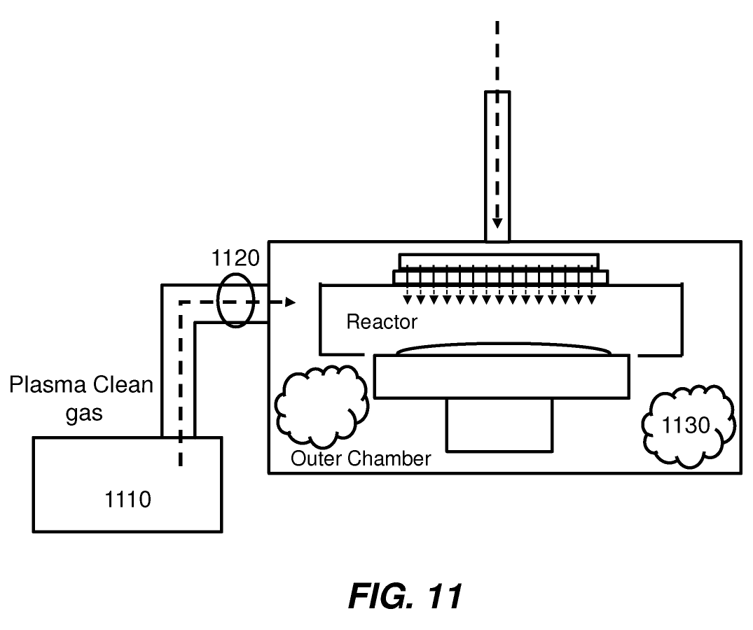

FIG. 11 illustrates a combined etching/deposition reactor according to various embodiments. In this example, a remote plasma source 1110 generates plasma that is delivered to the outer chamber as remote plasma 1130. Valve 1120 may be used to control delivery of the plasma to the outer chamber. As compared to the plasma generated in the embodiment of FIG. 10, the remote plasma of FIG. 11 provides a relatively high density of reactive radicals for chamber cleaning. The remote plasma 1130 may also provide a relatively low density of ions.

One advantage of the embodiment of FIG. 11 is that the remote plasma 1130 can be used to control buildup of residues in the outer chamber. In this embodiment, the remote plasma clean may be less efficient than a direct unconfined plasma (e.g., as used in FIG. 10). Further, because the components of the outer chamber are exposed to remote plasma conditions, they should preferably be fabricated from materials that are compatible with remote plasma exposure. The remote plasma source may also add cost and complexity to the system.

### J. Controller

Any of the apparatuses described herein may include a controller. In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. An apparatus for processing a substrate, the apparatus comprising:
a processing chamber comprising:
an outer chamber,
a reactor having an inlet and an outlet, the reactor being positioned within the outer chamber, and
a flowpath between the reactor and the outer chamber, and partially formed by the outlet;
a plasma generator configured to provide plasma in the reactor;
a substrate support; and
a movable component proximate to the reactor, wherein:
the movable component is adjustable and configured to vary flow along the flowpath between the reactor and the outer chamber.

2. The apparatus of claim 1, wherein:
the movable component is configured to be in a first position and a second position,
in the first position, the flowpath has a first flow conductance, and
in the second position, the flowpath has a second flow conductance less than the first flow conductance.

3. The apparatus of claim 2, wherein:
the first flow conductance is about 1 sccm/mTorr or greater, and
the second flow conductance is about 0.2 sccm/mTorr or less.

4. The apparatus of claim 1, wherein the movable component is a movable pressure control ring proximate the outlet to the reactor.

5. The apparatus of claim 4, wherein:
the pressure control ring is configured to be in a first position with respect to the outlet and a second position with respect to the outlet,
in the first position, the pressure control ring is farther from the outlet than in the second position,
in the first position, the flowpath has a first flow conductance, and
in the second position, the flowpath has a second flow conductance less than the first flow conductance.

6. The apparatus of claim 5, wherein:
the first flow conductance is about 1 sccm/mTorr or greater, and
the second flow conductance is about 0.2 sccm/mTorr or less.

7. The apparatus of claim 4, wherein:
the reactor is partially defined by a confinement shroud, and
the movable pressure control ring is below the confinement shroud.

8. The apparatus of claim 7, wherein the outlet is partially formed by a slotted or perforated portion of the confinement shroud.

9. The apparatus of claim 7, wherein the movable pressure control ring further comprises a seal configured to engage with the confinement shroud.

10. The apparatus of claim 4, wherein the movable pressure control ring is configured to move vertically within the processing chamber.

11. The apparatus of claim 4, wherein the inlet is configured to receive etch gases, deposition gases, and purge gases.

12. The apparatus of claim 4, wherein the movable pressure control ring encircles the substrate support.

13. The apparatus of claim 1, wherein the movable component is a movable wall coupled to the processing chamber, configured to move vertically, and configured to obstruct flow along the flowpath.

14. The apparatus of claim 13, wherein:
the movable wall is configured to split the reactor into an inner reactor region and a peripheral reactor region, and
the inner reactor region is radially interior of the movable wall, and
the peripheral reactor region is between the inner reactor region and the outer chamber.

15. The apparatus of claim 14, wherein:
the movable wall is configured to be in a first position and a second position,
in the first position:
the movable wall does not split the reactor into the inner reactor region and the peripheral reactor region, and
the flowpath has a first flow conductance, and
in the second position:
the movable wall splits the reactor into the inner reactor region and the peripheral reactor region,
the movable wall obstructs flow along the flowpath, and
the flowpath has a second flow conductance less than the first flow conductance.

16. The apparatus of claim 15, wherein when the movable wall splits the reactor into the inner reactor region and the peripheral reactor region, a lower portion of the movable wall is in contact with the substrate support.

17. The apparatus of claim 15, wherein:
the reactor is partially defined by a confinement shroud, and
when the movable wall splits the reactor into the inner reactor region and the peripheral reactor region, a lower portion of the movable wall is in contact with the confinement shroud.

18. The apparatus of claim 13, wherein the outlet is radially outwards of the movable wall.

19. The apparatus of claim 13, wherein the movable wall has a ring shape.

20. The apparatus of claim 13, further comprising a pocket above the reactor and configured to receive the movable wall.
